(19) United States
(12) Patent Application Publication
(10) Pub. No.: US 2024/0006191 A1
(43) Pub. Date: Jan. 4, 2024

(54) PROCESS FOR THE MANUFACTURE OF ENCAPSULATED SEMICONDUCTOR DIES AND/OR OF ENCAPSULATED SEMICONDUCTOR PACKAGES

(71) Applicants: Heraeus Materials Singapore Pte. Ltd., SINGAPORE (SG); HERAEUS DEUTSCHLAND GMBH & CO. KG., HANAU (DE)

(72) Inventors: Markus SCHEIBEL, Hanau (DE); Stefan MAUSNER, Hanau (DE); Sungsig KANG, Singapore (SG); Martin SATTLER, Hanau (DE); Anton-Zoran MIRIC, Hanau (DE); Li-San CHAN, Singapore (SG)

(21) Appl. No.: 18/255,299

(22) PCT Filed: Dec. 23, 2020
(86) PCT No.: PCT/SG2020/050774

§ 371 Date: May 31, 2023

(51) Int. Cl. H01L 21/56; C04B 28/04; C04B 28/06; C04B 28/10; H01L 23/29

(52) U.S. Cl. CPC H01L 21/568; C04B 28/04; C04B 28/06; C04B 28/105; H01L 23/291; C04B 2111/00844

(57) ABSTRACT

A process for the manufacture of encapsulated semiconductor dies and/or of encapsulated semiconductor packages or for the manufacture of an encapsulation of semiconductor dies and/or of semiconductor packages comprising the steps: (1) assembling a multitude of bare semiconductor dies on a temporary carrier, and (2) encapsulating the assembled bare semiconductor dies, characterized in that an aqueous hydraulic hardening inorganic cement preparation is applied as encapsulation agent in step (2).

The invention relates to an improved process for the manufacture of an encapsulation of semiconductor dies and/or of semiconductor packages or, respectively, for the manufacture of encapsulated semiconductor dies and/or of encapsulated semiconductor packages. The invention relates also to the encapsulated semiconductor dies or to the encapsulated semiconductor packages obtainable by the process.

Semiconductor dies include, for example, memory chips, logical function chips and the like.

The term “semiconductor package” used herein means a set comprising a small number of semiconductor dies, for example, at least 2 semiconductor dies, e.g. 2 to 5 or 2 to 10 semiconductor dies.

State of the art manufacture of bare semiconductor dies comprises structuring (including photolithographic structuring) of semiconductor wafers, optionally applying a conventional metallization for electrical contact purposes and finally dividing the structured semiconductor wafers into single semiconductor dies (so-called die singulation), i.e. into bare semiconductor dies lacking an electrically insulating and/or protective encapsulation. Dividing the structured wafers may be performed, for example, by diamond sawing or laser dicing. These processes are also known as so-called fan-out and fan-in wafer or panel level packaging.

In order to equip bare semiconductor dies with a protective and electrically insulating encapsulation, it is conventional to first put or fix them on a temporary carrier. The temporary carrier may be made of steel, quartz glass or glass, for example, and it may have a release tape for temporary fixing the bare semiconductor dies thereon.

The temporary fixing is carried out such that the bare semiconductor dies are arranged with an appropriate distance or gap between them, whereby said distance or gap defines space to be filled with an encapsulation agent. Hence, after placing the bare semiconductor dies on the temporary carrier an encapsulation agent in the form of a hardenable (curable) organic molding mass, e.g. an epoxy molding compound, is applied between and onto the bare semiconductor dies and is allowed to harden resulting in the formation of an organic polymeric composition, for example, a hardened epoxy polymeric composition or the like. The application may be carried out by conventional molding technique, for example, compression molding or transfer molding. The hardening is typically effected by application of heat resulting in object temperatures being reached in the range of, for example, 100 to 200° C. After the hardening a structure is formed which comprises the temporary carrier with the individual semiconductor dies thereon covered by an organic polymeric hood-like encapsulation.

The so formed structure comprised of the organic polymeric hood-like encapsulation comprising the semiconductor dies is then removed from the temporary carrier, the so-called debonding or carrier release. The carrier release may then be followed by successive steps of equipping the semiconductor dies with electrically insulating means and electrical interconnection at the dies' bottom or top face. Examples of conventional electrically insulating means include dielectric polymer, while examples of conventional electrical interconnection include redistributed layer of metal lines and contacts, for example, metal plating like copper plating.

Finally, the structure comprised of the hood-like organic polymeric encapsulation with the semiconductor dies being equipped with electrically insulating means and electrical interconnection is divided into individual encapsulated semiconductor dies or into encapsulated semiconductor packages, a process called “singulation” or “singulating”. Singulating may be carried out by sawing, for example, diamond sawing, or by laser cutting, for example. Finally, a multitude of encapsulated semiconductor dies and/or of encapsulated semiconductor packages, which can be used as electronic components, is obtained.

Not only the thermal hardening of said encapsulation agent but also the equipping of the semiconductor dies with electrically insulating means and electrical interconnection requires application of heat which is accompanied by remarkable object temperature changes and, as the case may be, volume changes of the encapsulation material in the course of which detrimental warpage phenomena and undesired die shift are likely to occur. Die shift means change of dies' position; for example, dies may move from a desired location causing an incapability to join to metal contacts. One such warpage phenomenon is an undesired bowing of the structure comprised of the temporary carrier with the hood-like organic polymeric encapsulation comprising the semiconductor dies during the thermal hardening of the encapsulation agent. Another warpage phenomenon is an undesired bowing of the removed hood-like organic polymeric encapsulation comprising the semiconductor dies during equipping the latter with electrically insulating means and electrical interconnection. As an undesired result of bowing and die shift at least some semiconductor dies may be shifted causing an incapability to properly join to metal contacts and thus, those shifted semiconductor dies need to be labeled as scrap. Such scrap can be detected during a quality and function check.

There is a desire to find a process for the manufacture of encapsulated semiconductor dies or of encapsulated semiconductor packages with a lower or even without scrap formation rate, i.e. a manufacturing process with less or even without scrap formation, or, in other words, with less or even without occurrence of the afore mentioned warpage phenomena. Warpage can be measured using Shadow Moiré method, for example, according to JEDEC standard JESD22-B108B or, if warpage is to be characterized at reflow soldering temperatures, according to JESD22-B112.

The applicant has found a surprising solution by using an encapsulation agent based on hydraulic hardenable inorganic cement.

The applicant's invention is a process for the manufacture of encapsulated semiconductor dies and/or of encapsulated semiconductor packages comprising the steps:
(1) assembling a multitude of bare semiconductor dies on a temporary carrier, and
(2) encapsulating the assembled bare semiconductor dies,
characterized in that an aqueous hydraulic hardening inorganic cement preparation is applied as encapsulation agent in step (2).

In an embodiment, the process may further comprise the steps: (3) removing the temporary carrier, and (4) singulating the encapsulated semiconductor dies and/or encapsulated semiconductor packages. In such embodiment, the process is a process for the manufacture of encapsulated semiconductor dies and/or of encapsulated semiconductor packages comprising the steps:
(1) assembling a multitude of bare semiconductor dies on a temporary carrier,
(2) encapsulating the assembled bare semiconductor dies,
(3) removing the temporary carrier, and
(4) singulating the encapsulated semiconductor dies and/or encapsulated semiconductor packages,
characterized in that an aqueous hydraulic hardening inorganic cement preparation is applied as encapsulation agent in step (2).

To prevent misunderstandings, the term “hydraulic hardening” used in this disclosure and in the claims means “hydraulic curing” or “hydraulic setting”, i.e. setting in the presence of water or after addition of water, respectively. The hydraulic hardening process may proceed without or with support of compression (mechanical pressure).

The invention may also be understood as a process for the manufacture of an encapsulation of semiconductor dies and/or of semiconductor packages comprising the steps:
(1) assembling a multitude of bare semiconductor dies on a temporary carrier, and
(2) encapsulating the assembled bare semiconductor dies,
characterized in that an aqueous hydraulic hardening inorganic cement preparation is applied as encapsulation agent in step (2).

In an embodiment, this process for the manufacture of an encapsulation of semiconductor dies or of semiconductor packages may also further comprise the steps: (3) removing the temporary carrier, and (4) singulating the encapsulated semiconductor dies and/or encapsulated semiconductor packages. In such embodiment, the process is a process for the manufacture of an encapsulation of semiconductor dies and/or of semiconductor packages comprising the steps:
(1) assembling a multitude of bare semiconductor dies on a temporary carrier,
(2) encapsulating the assembled bare semiconductor dies,
(3) removing the temporary carrier, and
(4) singulating the encapsulated semiconductor dies and/or encapsulated semiconductor packages,
characterized in that an aqueous hydraulic hardening inorganic cement preparation is applied as encapsulation agent in step (2).

In step (1) a multitude of bare semiconductor dies is assembled on a temporary carrier.

Bare semiconductor dies can be obtained in the conventional manner as has been described above. There are two options for assembling the bare semiconductor dies, face-down assembly or face-up assembly. Face-down assembly means that the dies' faces are directed towards the temporary carrier, whereas face-up assembly means exactly the opposite, i.e. here the dies are assembled with their faces directed away from the temporary carrier. To prevent misunderstandings, “dies' faces” means the semiconductor dies' critical active areas for interconnection.

Typically, the temporary carrier takes the form of a sheet. The temporary carrier may be made of, for example, quartz glass, glass, polymer or metal, for example, steel. The temporary carrier may be equipped with a release tape.

The bare semiconductor dies are assembled so as to have an appropriate distance or gap between themselves. That distance (gap width) lies in the range of, for example, 30 to 70 μm and it defines space to be filled with the aqueous hydraulic hardening inorganic cement preparation during step (2).

In step (2) the assembled semiconductor dies are encapsulated, wherein an aqueous hydraulic hardenable inorganic cement preparation is applied as encapsulation agent. To this end, after the bare semiconductor dies have been placed on the temporary carrier or on its release tape, the aqueous hydraulic hardening inorganic cement preparation is applied onto and between the bare semiconductor dies and is allowed to harden hydraulically.

Herein a distinction is made between hydraulic hardenable inorganic cement, aqueous hydraulic hardening inorganic cement preparation and hydraulic hardened inorganic cement composition. Hydraulic hardenable inorganic cement, which is a powder, can be mixed with water to yield an aqueous hydraulic hardening inorganic cement preparation in particular in the form of a viscoelastic, for example, pasty or flowable mass, also known as cement paste or cement glue. An aqueous hydraulic hardening inorganic cement preparation can be hardened hydraulically to obtain a hydraulic hardened inorganic cement composition in the form of a hard solid, also known as cement stone. In other words, hydraulic hardened inorganic cement composition is based on hydraulic hardenable inorganic cement. Hydraulic hardened inorganic cement composition or cement stone is essentially or completely water insoluble.

The hydraulic hardened inorganic cement composition may consist of hydraulic hardened inorganic cement. The hydraulic hardened inorganic cement is based on a hydraulic hardenable inorganic cement and the hydraulic hardened inorganic cement composition may be made by mixing of hydraulic hardenable inorganic cement with water to form a hydraulic hardening inorganic cement preparation, followed by applying, hydraulically hardening and drying it.

In the alternative, it is also possible that the hydraulic hardened inorganic cement composition comprises the hydraulic hardened inorganic cement only as a matrix-forming constituent. In such case the hydraulic hardened inorganic cement composition may comprise one or more further constituents (constituents other than hydraulic hardened inorganic cement) in a total amount of, for example, 0.5 to 98 wt.-% (% by weight), i.e. it may be comprised of, for example, 2 to 99.5 wt.-% of hydraulic hardened inorganic cement and, accordingly, 0.5 to 98 wt.-% of one or more further constituents. Here, the hydraulic hardened inorganic cement is based on a hydraulic hardenable inorganic cement and the one or more further constituents, and the hydraulic hardened inorganic cement composition may be made by mixing of hydraulic hardenable inorganic cement with water and with the one or more further constituents to form an aqueous hydraulic hardening inorganic cement preparation, followed by applying, hydraulically hardening and drying it.

If the hydraulic hardened inorganic cement composition comprises at least one further constituent, the aqueous hydraulic hardening inorganic cement preparation comprises, apart from water, also at least one further constituent, in particular, the same further constituent(s) like the hydraulic hardened inorganic cement composition. Such further constituents can already be added to or mixed into the hydraulic hardenable inorganic cement. It is also possible to mix the hydraulic hardenable inorganic cement with all further constituents first without addition of water and then to further mix with water to produce the aqueous hydraulic hardening inorganic cement preparation. In the alternative, the at least one further constituent can be added before, during or after the addition of water. Amount, time and sequence of addition depend on chemical and physical properties during production of the aqueous hydraulic hardening inorganic cement preparation with a view to its homogeneity and handling; from a practical point of view the skilled person will orient itself at the miscibility and the behavior of the material, for example, its so-called pot life.

The at least one further constituent may be comprised in a total amount of, for example, 0.1 to 92 wt.-%, relative to the aqueous hydraulic hardening inorganic cement preparation.

The hydraulic hardenable inorganic cement as such is a powder. It may be Portland cement, alumina cement, magnesium oxide cement, phosphate cement like zinc phosphate cement or, preferably, magnesium phosphate cement.

Examples of said further constituents comprise fillers, fibers, flow enhancers, setting retarders, defoamers, water-miscible organic solvents, surfactants, wetting agents and adhesion promoters.

Examples of fillers comprise glass; calcium sulfate; barium sulfate; simple and complex silicates comprising sodium, potassium, calcium, aluminum, magnesium, iron and/or zirconium; simple and complex aluminates comprising calcium, magnesium and/or zirconium; simple and complex titanates comprising calcium, aluminum, magnesium, barium and/or zirconium; simple and complex zirconates comprising calcium, aluminum and/or magnesium; zirconium dioxide; titanium dioxide; aluminum oxide; silicon dioxide, in particular as silica or quartz; silicon carbide; aluminum nitride; boron nitride and silicon nitride. Herein a distinction is made between simple and complex silicates, aluminates, titanates and zirconates. The complex silicates, aluminates, titanates and zirconates are not to be understood as complex compounds in the sense of coordination compounds; rather, silicates, aluminates, titanates and zirconates having more than one type of cation are meant here, like for example sodium aluminum silicate, calcium aluminum silicate, lead zirconium titanate etc. The presence of fillers may have an advantageous effect on the thermal conductivity and/or the thermal expansion behavior of the hydraulic hardened inorganic cement composition.

Examples of fibers include glass fibers, basalt fibers, boron fibers and ceramic fibers, for example silicon carbide fibers and aluminum oxide fibers, rock wool fibers, wollastonite fibers and aramid fibers. The presence of fibers may have an advantageous effect on stress distribution and crack prevention within the hydraulic hardened inorganic cement composition.

The aqueous hydraulic hardening inorganic cement preparation may have a water content of, for example, 6 to 25 wt.-%.

The viscosity of a freshly made (within 5 minutes upon finishing the preparation) aqueous hydraulic hardening inorganic cement preparation may be in the range of, for example, 0.1 to 20 Pa-s (on determination by rotational viscometry, plate-plate measuring principle, plate diameter 25 mm, measuring gap 1 mm, sample temperature 20° C.).

The encapsulation step (2) can be carried out in a conventional manner by applying the aqueous hydraulic hardening inorganic cement preparation onto and between the bare semiconductor dies on the temporary carrier and allowing it to harden hydraulically and to dry. Examples of application methods include conventional molding technique like, for example, compression molding or transfer molding. The aqueous hydraulic hardening inorganic cement preparation is applied so as to form an encapsulation having a thickness of, for example, 30 to 1000 μm, in particular 50 to 300 μm on top of the semiconductor dies.

The hydraulic hardening may be carried out at ambient conditions, for example, at ambient object temperature in the range of, for example, 20 to 25° C. and it may take in the range of, for example, 1 minute to 6 hours. If a shorter duration is desired, the object temperature can be raised and the hydraulic hardening can then take place at an object temperature of 30 to 90° C. and it may then be finished within 30 seconds to 1 hour, for example.

The drying, i.e. the removal of water, follows the hydraulic hardening and it may require, for example, 0.5 to 6 hours at an object temperature of, for example, 80 to 300° C. The drying may be vacuum supported.

After conclusion of the hydraulic hardening and the drying, i.e. after conclusion of step (2), a structure is obtained which comprises the temporary carrier with the individual semiconductor dies thereon covered by a hood-like encapsulation in the form of a cover of hydraulic hardened inorganic cement composition, i.e. a cover of cement stone.

The benefit of carrying out step (2) with an aqueous hydraulic hardening inorganic cement preparation as encapsulation agent instead of a prior art organic molding composition type encapsulation agent is that undesired warpage and/or die shift phenomena like those mentioned above can be prevented to quite an extent or even completely. Less scrap in terms of encapsulated semiconductor dies disenabling proper electrical contacting is produced. However, prevention of scrap formation is not the only benefit; the replacement of the prior art organic molding composition type encapsulation agent by the aqueous hydraulic hardening inorganic cement preparation has some additional beneficial aspects like less chemical hazard and no fire hazard. Advantages of the cement stone encapsulation include no glass transition and higher thermal resistance when compared with the prior art organic polymeric composition type encapsulation.

In step (3) the temporary carrier is removed; i.e. it is released or debonded from the structure formed in step (2) or, more precisely, from the structure which comprises the temporary carrier with the individual semiconductor dies thereon covered by the hood-like encapsulation of cement stone. As a result of the temporary carrier being removed, a structure comprised of the debonded hood-like encapsulation of cement stone comprising the semiconductor dies is obtained.

Between steps (3) and (4) there may be an intermediate step (3′) of providing encapsulated semiconductor dies with electrical insulation means and electrical interconnection. Examples of electrical insulation means and electrical interconnection have been disclosed above. In case the semiconductor dies had been assembled face-down on the temporary carrier in step (1), both, electrical insulation means and electrical interconnection may be provided at the bottom face of the encapsulated semiconductor dies. In the other case the semiconductor dies had been assembled face-up on the temporary carrier in step (1), both, electrical insulation means and electrical interconnection may be provided at the top face of the encapsulated semiconductor dies; however, here, prior to the provision of the electrical insulation means and electrical interconnection access paths need to be prepared through the cement stone encapsulation covering the top face.

In step (4) the encapsulated semiconductor dies and/or the encapsulated semiconductor packages are singulated. This may be performed by conventional methods known by the skilled person. Examples of such methods include diamond sawing and laser cutting.

As already mentioned above a multitude of encapsulated semiconductor dies and/or of encapsulated semiconductor packages is obtained by the process of the invention. Hence, the process of the invention can be performed such that encapsulated semiconductor dies as well as encapsulated semiconductor packages are produced. To this end, assembly step (1) and singulation step (4) may be adapted accordingly, especially with regard to an appropriate selection of gap widths between the semiconductor dies.

The present invention relates also to encapsulated semiconductor dies or encapsulated semiconductor packages obtainable by the above disclosed process in any of its above disclosed embodiments.

The present invention relates also to encapsulated semiconductor dies comprising or comprised of a bare semiconductor die and an encapsulation of a hydraulic hardened inorganic cement composition in any of the above disclosed embodiments, including in particular the above disclosed embodiments relating to the composition of the hydraulic hardened inorganic cement composition.

The present invention relates also to encapsulated semiconductor packages comprising or comprised of at least 2 semiconductor dies and an encapsulation of a hydraulic hardened inorganic cement composition in any of the above disclosed embodiments, including in particular the above disclosed embodiments relating to the composition of the hydraulic hardened inorganic cement composition.

### WORKING EXAMPLE

5 pbw (parts by weight) of a magnesium oxide cement powder with a maximum particle size of 50 μm, 6 pbw 2-imidazolidinone, 11 pbw microsilica with a maximum particle size of 5 μm, 65 pbw aluminum oxide powder with a maximum particle size of 100 μm and 12 pbw water were mixed to form an aqueous hydraulic hardening inorganic cement preparation.

300 μm thick bare semiconductor dies having a square format of 3 mm×3 mm were assembled on a release tape of a steel sheet carrier in a regular arrangement of semiconductor packages (3 semiconductors per package) with a gap width of 300 μm between the packages and with a 50 μm gap width between the individual dies. The aqueous hydraulic hardening inorganic cement preparation was overmolded between and in 150 μm thickness on top of the semiconductor dies. The so-applied aqueous hydraulic hardening inorganic cement preparation of the so-formed structure was allowed to harden hydraulically for 4 hours at 20° C. Then the structure was heated up to 90° C. object temperature in an oven at a heating rate of 1 K/min and kept at 90° C. for 1 hour. Thereafter, the object temperature was increased to 160° C. at a heating rate of 1 K/min and kept at 160° C. for 1 hour. After cooling, the structure so obtained was subject to diamond sawing in the course of which the encapsulated semiconductor packages were singulated.

1. A process for the manufacture of encapsulated semiconductor dies and/or of encapsulated semiconductor packages or for the manufacture of an encapsulation of semiconductor dies and/or of semiconductor packages comprising the steps:
(1) assembling a multitude of bare semiconductor dies on a temporary carrier, and
(2) encapsulating the assembled bare semiconductor dies,
wherein an aqueous hydraulic hardening inorganic cement preparation is applied as encapsulation agent in step (2).

2. The process of claim 1, further comprising the steps:
(3) removing the temporary carrier, and
(4) singulating the encapsulated semiconductor dies and/or encapsulated semiconductor packages.

3. The process of claim 1, wherein the bare semiconductor dies are assembled so as to have a distance in the range of 30 to 70 μm between themselves, wherein the distance defines space to be filled with the aqueous hydraulic hardening inorganic cement preparation during step (2).

4. The process of claim 1, wherein step (2) is performed such that the aqueous hydraulic hardening inorganic cement preparation is applied onto and between the bare semiconductor dies and is allowed to harden hydraulically and to dry.

5. The process claim 1, wherein the aqueous hydraulic hardening inorganic cement preparation is made by mixing hydraulic hardenable inorganic cement with water or by mixing of hydraulic hardenable inorganic cement with water and with at least one further constituent.

6. The process of claim 5, wherein the hydraulic hardenable inorganic cement is a powder selected from the group consisting of Portland cement, alumina cement, magnesium oxide cement, and phosphate cement.

7. The process of claim 1, wherein the application of the aqueous hydraulic hardening inorganic cement preparation is carried out by compression molding or by transfer molding.

8. The process of claim 1, wherein the aqueous hydraulic hardening inorganic cement preparation is applied so as to form an encapsulation having a thickness of 30 to 1000 μm on top of the semiconductor dies.

9. The process of claim 2 to comprising an intermediate step (3′) between steps (3) and (4) of providing encapsulated semiconductor dies with electrical insulation means and electrical interconnection.

10. The process of claim 2, wherein the singulating of step (4) is performed by diamond sawing or laser cutting.

11. An encapsulated semiconductor die or an encapsulated semiconductor package obtainable by a process of claim 1.

12. An encapsulated semiconductor die comprising or comprised of a bare semiconductor die and an encapsulation of a hydraulic hardened inorganic cement composition or an encapsulated semiconductor package comprising or comprised of at least 2 bare semiconductor dies and an encapsulation of a hydraulic hardened inorganic cement composition.

13. The encapsulated semiconductor die or the encapsulated semiconductor package of claim 12, wherein the hydraulic hardened inorganic cement composition consists of hydraulic hardened inorganic cement.

14. The encapsulated semiconductor die or the encapsulated semiconductor package of claim 12, wherein the hydraulic hardened inorganic cement composition consists of 2 to 99.5 wt.-% of hydraulic hardened inorganic cement and 0.5 to 98 wt.-% of one or more further constituents.

15. The encapsulated semiconductor die or the encapsulated semiconductor package of claim 12, wherein the hydraulic hardened inorganic cement composition is based on hydraulic hardenable inorganic cement selected from the group consisting of Portland cement, alumina cement, magnesium oxide cement and phosphate cement.
